(19) United States
(12) Patent Application Publication
(10) Pub. No.: US 2008/0081415 A1
(43) Pub. Date: Apr. 3, 2008

(54) Method of Manufacturing Flash Memory Device

(75) Inventor: Byoung-Ki Lee, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/747,453

(22) Filed: May 11, 2007

(30) Foreign Application Priority Data
Sep. 29, 2006 (KR) 2006-96213

(51) Int. Cl. H01L 21/336

(52) U.S. Cl. 438/257; 257/E21.409

(57) ABSTRACT

A method of manufacturing a flash memory device. According to a method of manufacturing a flash memory device, since it comprises the steps of providing a semiconductor substrate including a cell region and a peripheral circuit region, forming a first oxide film and a nitride film subsequently over the semiconductor of the cell region, and forming the first oxide film, a buffer poly film and the nitride film over the semiconductor of the peripheral circuit region, forming a device isolation film by performing a process of the Self Align Shallow Trench Isolation (STI) over the semiconductor substrate including the first oxide film, the buffer poly film and the nitride film, forming a second oxide film and a control gate film over the whole structure including the device isolation film, and performing a gate pattering process as to the whole structure using a gate mask pattern; the nitride films storing charges are insulated on the respective gate to prevent a current leakage and a thinning phenomenon that may occur on a gate oxide film.

### CROSS-REFERENCES TO RELATED APPLICATIONS

The priority of Korean patent application number 10-2006-96213, filed on Sep. 29, 2006, the entire disclosure which is incorporated by reference in its entirety, is claimed.

### BACKGROUND OF THE INVENTION

The invention relates to a method of manufacturing flash memory device and, more particularly, to a method of manufacturing a flash memory device type of Silicon/Oxide/Nitride/Oxide/Silicon (SONOS).

Typically, a cell transistor of a flash memory device has a stacked gate structure. The stacked gate structure is formed by stacking subsequently a gate oxide film, a floating gate electrode, an integrated insulation film, and a control gate electrode, over a channel region of a cell transistor. However, a flash memory device type of SONOS includes a gate oxide film forming a direct tunneling film, a nitride film for storing charge, an oxide film used as a charge blocking layer, and a control gate electrode.

That is, in prior flash memory devices, charges are stored on a floating gate formed of poly silicon; however, in the flash memory device type of SONOS, charges are stored on a nitride film. Accordingly, there is a problem in the prior flash memory in that when minute defect is present on a floating gate, the retention time of charges is prominently lowered. However, in the flash memory device type of SONOS, a nitride film is formed, rather than poly silicon, and thus sensitivity to the process defect becomes relatively small due to the characteristics of nitride film.

In addition, in the prior flash memory, since a tunnel oxide film having a thickness of about equal to or greater than 70 Å is formed on the lower part of a floating gate, there is a limitation to a low voltage operation and a high speed operation. However, in the flash memory device type of SONOS, since a relatively thin direct oxide film is formed on the lower part of a nitride film, it is possible to drive a memory device at high speed while using low voltage and lower power.

When manufacturing a flash memory device type of SONOS, a device isolation layer is formed as Shallow Trench Isolation (STI) on the upper part of a semiconductor substrate and further a gate oxide film, a nitride film for storing charge, an oxide film used as a charge blocking film, and a nitride film used as a control gate electrode, etc, are formed over a semiconductor substrate including the device isolation layer. Subsequently, a gate pattern process is performed to form a gate.

Here, when the flash memory type of SONOS is formed in the aforementioned way, the nitride film is formed continuously in a gate direction without being separated into the respective gate even after the gate pattern process is performed (see FIG. 1). As a result, current is leaked through the nitride film to deteriorate device characteristics. In addition, when the gate oxide film is formed, a thinning phenomenon, on which a trench edge is formed to be thinner than other part, occurs to deteriorate device characteristics.

### SUMMARY OF THE INVENTION

To solve the problem, the invention provides a method of manufacturing a flash memory device in which a flash memory device type of SONOS is manufactured using a Self Align STI (Shallow Trench Isolation) process, wherein, nitride films storing charges are formed separately on the respective cell transistor and thus a thinning phenomenon, which may occur on a gate oxide film, can be prevented.

A method of manufacturing a flash memory device according to invention includes the steps of providing a semiconductor substrate including a cell region and a peripheral circuit region, forming a first oxide film and a nitride film subsequently over the semiconductor of the cell region, and forming the first oxide film, a buffer poly film and the nitride film over the semiconductor of the peripheral circuit region, forming a device isolation film by performing a process of the Self Align STI over the semiconductor substrate including the first oxide film, the buffer poly film and the nitride film, forming a second oxide film and a control gate film over the whole structure including the device isolation film, and performing a gate pattering process as to the whole structure using a gate mask pattern.

The step of forming a device isolation film preferably includes the steps of forming a second nitride film over the first nitride film, forming a trench to expose a portion of the semiconductor substrate by using an etching process, forming an insulation film for the device isolation film over the whole structure including the trench to bury the trench, and planarizing over the whole structure to form the device isolation film.

The step of planarizing preferably includes Chemical Mechanical Polishing (CMP) process.

The device isolation film is preferably formed and then the first nitride film on the peripheral circuit region is removed.

The first oxide film on the cell region is preferably a direct tunneling oxide film and the first oxide film on the peripheral circuit region is preferably a gate oxide film.

The first nitride film is preferably a film storing charges and the second oxide film is preferably a film blocking charges.

The control gate film preferably includes a metal gate film and a conductive film.

When a transistor is formed on the peripheral circuit region, the conductive film and the buffer poly film are preferably formed to be connected electrically.

When a transistor is formed by performing the gate patterning process, the first nitride films formed on the respective transistor are preferably insulated from each other.

The second oxide film is preferably a stacked structure of at least one of (and possibly any two of or all three of) Al₂O₃, HfO₂, and ZrO₂.

### BRIEF DESCRIPTION OF THE DRAWINGS

The accompanying drawings, which are included to provide a further understanding of the invention and are incorporated in and constitute a part of this disclosure, illustrate embodiments of the invention and together with the description serve to explain the principle of the invention. In the drawings:

FIG. 1 is a sectional view showing a flash memory device manufactured according to the prior art.

FIGS. 2a to 6a and 2b to 6b are sectional views showing the flash memory devices manufactured subsequently by the method according to the invention.

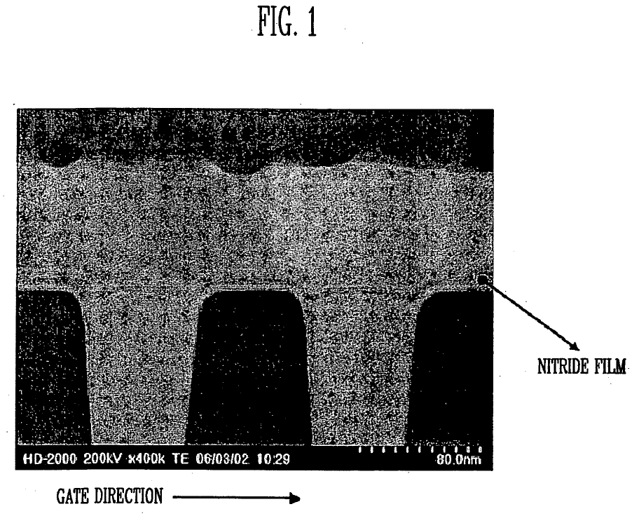

### DESCRIPTION OF SPECIFIC EMBODIMENTS

Reference will now be made in detail to the preferred embodiments of the invention, examples of which are illustrated in the accompanying drawings.

In the following, an embodiment of the invention is described.

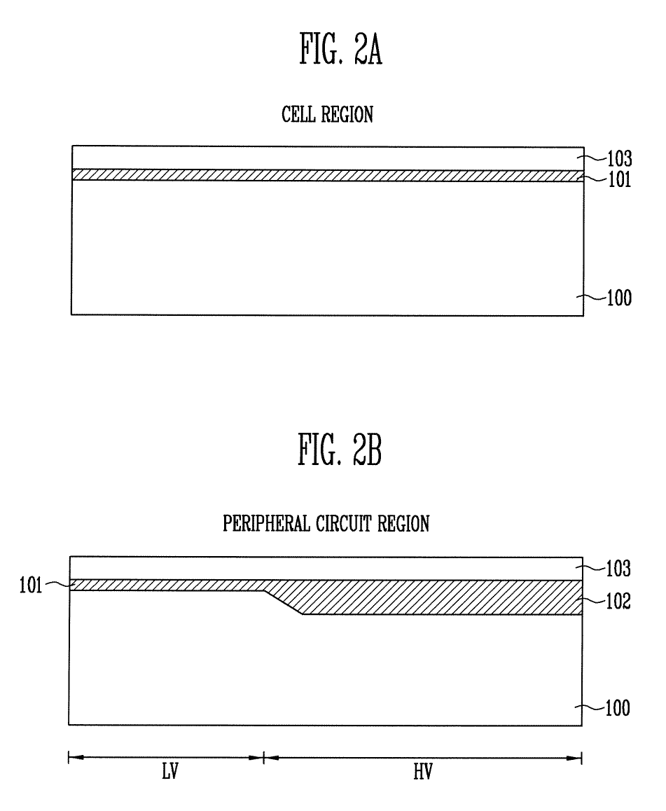

Referring to FIGS. 2a and 2b, a screen oxide film (not shown) is formed over a semiconductor substrate 100 including a cell region and a peripheral circuit region, and well ions are injected. Subsequently, ion injection processes of various thresholds voltages (Vₜ) forming a low voltage region (LV) and a high voltage (HV) region, etc. are performed. In subsequent steps, a first oxide film is formed on the semiconductor substrate 100. The first oxide film includes a low voltage gate oxide film 101 and a high voltage gate oxide film 102. Further, a buffer poly film 103 is formed over the first oxide film.

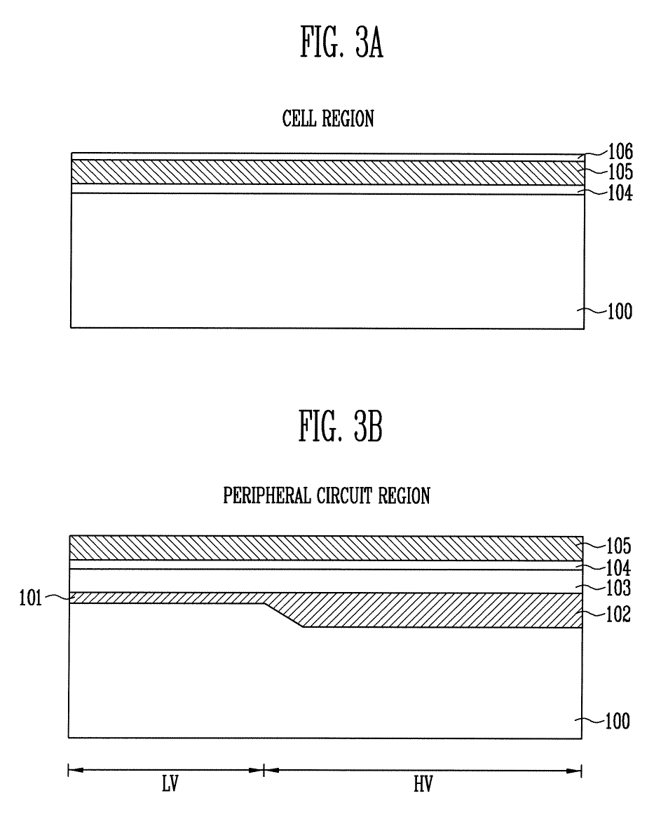

Referring to FIGS. 3a and 3b, a first mask pattern (not shown) that opens a cell region and closes a peripheral circuit region over the buffer ploy film 103, and the buffer poly film 103 (see FIGS. 2a and 2b) formed on a cell region is etched and removed using the first mask pattern. At this time, the low voltage gate oxide film 101 (see FIGS. 2a and 2b) formed on a cell region serves as an etching stopper. Additionally, a boundary region where the buffer poly film is etched is etched to incline 70 to 85 degrees.

Subsequently, an etching process is performed using the buffer poly film 103 as an etching mask to remove the low voltage gate oxide film 101 formed over the semiconductor substrate 100 of a cell region. Then, after a threshold voltage (Vₜ) ion injection process is performed, and the second oxide film 104 serving as a direct tunneling oxide film and the first nitride film 105 storing charges are stacked subsequently over the whole structure. In subsequent, a buffer oxide film 106 protecting the first nitride film 105 is formed over the whole first nitride film 105. Subsequently, a second mask pattern (not shown) that blocks a cell region and opens a peripheral circuit region is formed, and the buffer oxide film 106 on the peripheral circuit region is etched and removed by using the second mask pattern.

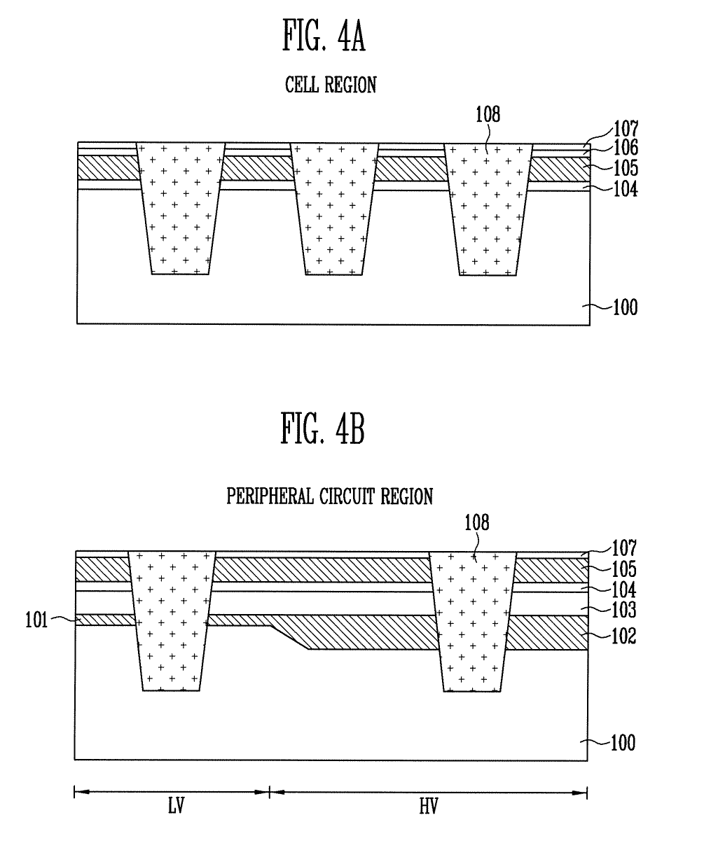

Referring to FIGS. 4a and 4b, a device isolation film 108 is formed using a Self Align Shallow Trench Isolation (STI) process.

In more details, first, a second nitride film 107 for a CMP and a third mask pattern (not shown) are formed over the first nitride film 105 and the buffer oxide film 106. In subsequent steps, en etching process is preformed using the third mask pattern to form a trench such that a portion of the semiconductor substrate 100 to be exposed. An insulation film for a device isolation film is formed subsequently over the whole structure including the trench such that the trench is gap filled. In subsequent steps, a planarization process is performed over the whole structure to form the device isolation film 108.

At this time, preferably, the planarization process is performed using a Chemical Mechanical Polishing (CMP) process.

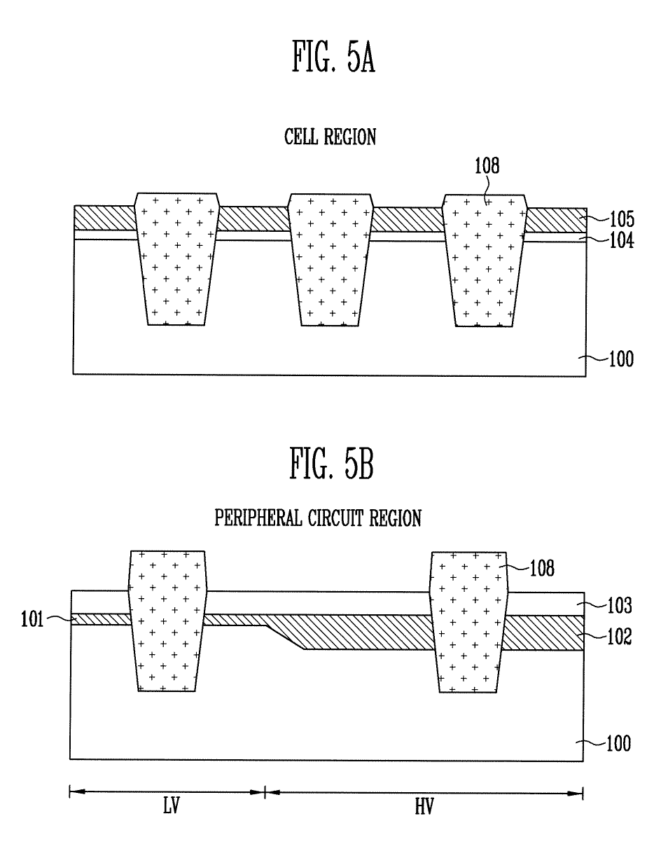

Referring to FIGS. 5a and 5b, the second nitride film 107 (see FIGS. 4a and 4b) on the cell region and the device isolation region, and the first nitride film 105 (see FIGS. 4a and 4b) are removed. At this time, the buffer oxide film 106 (see FIGS. 4a and 4b) on the cell region serves as an etching stopper, and the second oxide film 104 (see FIGS. 4a and 4b) on the peripheral circuit region serves as an etching stopper. Subsequently, the buffer oxide film 106 on the cell region and the second oxide film 104 on the peripheral circuit region are removed using well known method to expose the upper part of the device isolation film 108.

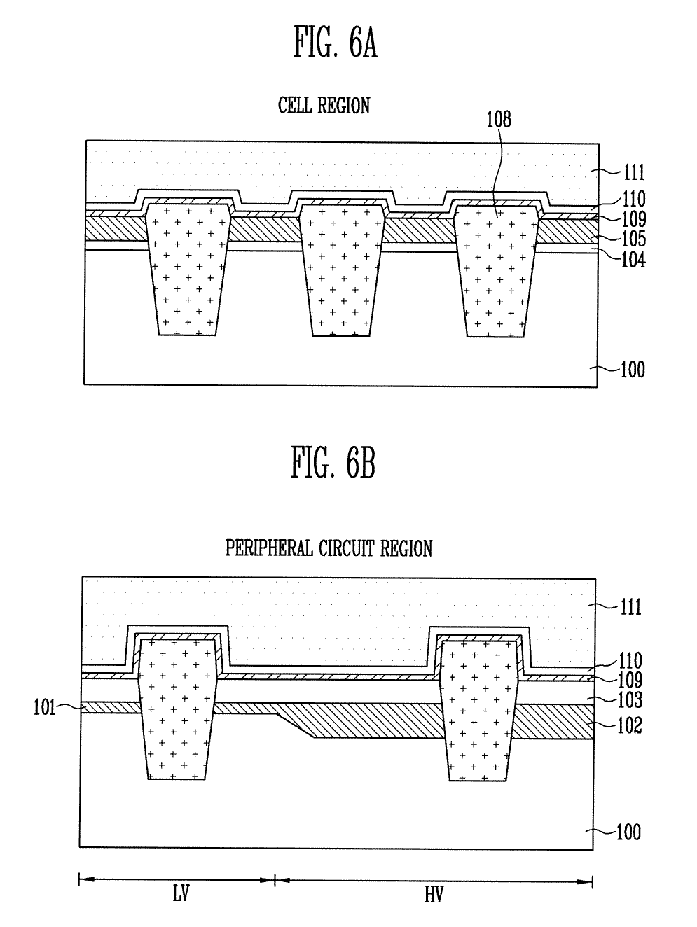

Referring to FIGS. 6a and 6b, a third oxide film 109 used as a charge blocking film is formed over the whole structure including the device isolation film 108, and a metal gate film 110 forming a control gate film and a conductive film 111 are formed over the third oxide film 109. At this time, the third oxide film 109 is formed by stacking at least one of Al₂O₃, HfO₂, and ZrO₂.

In addition, a fourth mask pattern (not shown) as a hard mask in formed over the conductive film 111, and a gate pattering process with respect to the cell region is performed using the fourth mask pattern. At this time, the third oxide film 109 serves as an etching stopper. In subsequent steps, the third oxide film 109, the first nitride film 105, and the gate oxide film 104 formed on the cell region are etched to form a transistor. At this time, the first nitride film 105 is formed separately on the respective transistor and thus the current leakage, which may occurs in the prior art, can be prevented.

Subsequently, a fifth mask pattern (not shown) that blocks a cell region and opens a peripheral circuit region is formed and then a contact plug is formed on the peripheral region to connect the conductive film 111 with the buffer poly film 103 to complete a peripheral circuit transistor.

According to a method of manufacturing a flash memory device according to the invention, when the flash memory device type of SONOS, a gate is formed by the Self Align STI and thus the nitride film storing charges is formed separately on the respective gate; therefore, a thinning that may occur on a gate oxide film can be prevented and thereby manufacturing a flash memory device which is stable and has good characteristics.

What is claimed is:

1. A method of manufacturing a flash memory device comprising steps of:
providing a semiconductor substrate including a cell region and a peripheral circuit region;
forming a first oxide film and a nitride film subsequently over the semiconductor of the cell region, and forming the first oxide film, a buffer poly film and the nitride film over the semiconductor of the peripheral circuit region;
forming a device isolation film by performing a Self Align Shallow Trench Isolation (STI) process over the semiconductor substrate including the first oxide film, the buffer poly film, and the nitride film;
forming a second oxide film and a control gate film over the whole structure including the device isolation film; and
performing a gate patterning process on the whole structure using a gate mask pattern.

2. A method of manufacturing a flash memory device according to claim 1, wherein the step of forming a device isolation film includes the steps of:
forming a second nitride film over the first nitride film;
forming a trench to expose a portion of the semiconductor substrate by using an etching process;
forming an insulation film for the device isolation film over the whole structure including the trench to bury the trench; and
planarizing over the whole structure to form the device isolation film.

3. A method of manufacturing a flash memory device according to claim 2, wherein the step of planarizing includes a Chemical Mechanical Polishing (CMP) process.

4. A method of manufacturing a flash memory device according to claim 1, comprising forming the device isolation film and then removing the first nitride film on the peripheral circuit region.

5. A method of manufacturing a flash memory device according to claim 1, wherein the first oxide film on the cell region is a direct tunneling oxide film and the first oxide film on the peripheral circuit region is a gate oxide film.

6. A method of manufacturing a flash memory device according to claim 1, wherein the first nitride film is a film storing charges and the second oxide film is a film blocking charges.

7. A method of manufacturing a flash memory device according to claim 1, wherein the control gate film includes a metal gate film and a conductive film.

8. A method of manufacturing a flash memory device according to claim 7, comprising when forming transistor is formed on the peripheral circuit region, forming the conductive film and the buffer poly film to be connected electrically.

9. A method of manufacturing a flash memory device according to claim 1, wherein when a transistor is formed by performing the gate patterning process, the first nitride films formed on the respective transistor are insulated to each other.

10. A method of manufacturing a flash memory device according to claim 1, wherein the second oxide film is a stacked structure of at least one of Al₂O₃, HfO₂, and ZrO₂.
